(19) United States
(12) Patent Application Publication
(10) Pub. No.: US 2025/0155505 A1
(43) Pub. Date: May 15, 2025

(54) MOTOR FAILURE DIAGNOSIS SYSTEM AND MOTOR FAILURE DIAGNOSIS METHOD

(71) Applicant: HL Mando Corporation, Pyeongtaek-si (KR)

(72) Inventor: Jaesang PARK, Pyeongtaek-si (KR)

(21) Appl. No.: 18/754,510

(22) Filed: Jun. 26, 2024

(30) Foreign Application Priority Data
Nov. 15, 2023 (KR) 10-2023-0158364

(51) Int. Cl. G01R 31/34; H02P 21/00; H02P 21/14; H02P 27/08; H02P 29/024

(52) U.S. Cl. CPC G01R 31/343; H02P 21/0003; H02P 21/14; H02P 27/08; H02P 29/024

(57) ABSTRACT

Disclosed herein are a motor failure diagnosis system and a motor failure diagnosis method. The motor failure diagnosis system includes a voltage diagnosis part calculating voltage based on duty information input into an inverter that outputs a three-phase signal to a motor, and comparing voltage output from a PI controller that receives current for operating the motor and outputs voltage, with voltage calculated based on the duty information input into the inverter, thereby diagnosing failure between the PI controller and the inverter.

### CROSS REFERENCE TO RELATED APPLICATION

The present application claims benefit and priority to Korean Patent Application No. 10-2023-0158364, filed on Nov. 15, 2023, with the Korean Intellectual Property Office, the disclosure of which is incorporated herein in its entirety by reference.

### TECHNICAL FIELD

The present disclosure relates to a motor failure diagnosis system and a motor failure diagnosis method, and more specifically, to a motor failure diagnosis system and a motor failure diagnosis method that can diagnose the failure of elements for driving a motor.

### BACKGROUND

In general, a motor is operated to produce output according to a user's request. For example, when applied to a vehicle, the motor is operated to produce output corresponding to a driver's request.

For the safety of the driver in the vehicle, the failure of the motor is diagnosed so that the motor or the vehicle is controlled. Specifically, the motor failure is diagnosed by comparing sensor detection information with information for motor output.

In this case, the motor failure may be diagnosed, but there is a problem in that it is difficult to determine whether there is an error in sensor detection or which component of a device for driving the motor has an error.

That is, it may be necessary to verify information for determining the failure.

In other words, when such a motor is applied to the vehicle, valid information for motor failure diagnosis should be used to ensure a driver's safety.

### SUMMARY

In view of the above, the present disclosure provides a motor failure diagnosis system and a motor failure diagnosis method that can diagnose a failure in each component outputting signals from an input signal for driving a motor to a final signal.

According to embodiments of the present disclosure, a motor failure diagnosis system includes a voltage diagnosis part calculating voltage based on duty information input into an inverter that outputs a three-phase signal to a motor, and comparing voltage output from a PI controller that receives current for operating the motor and outputs voltage, with voltage calculated based on the duty information input into the inverter, thereby diagnosing failure between the PI controller and the inverter.

The voltage diagnosis part may diagnose failure of a first transformation that transforms voltage information of the PI controller into a vector and transmits the information.

The motor failure diagnosis system may further include a current diagnosis part calculating the voltage output from the PI controller as a current, and comparing a current input into the PI controller with the current calculated based on the voltage output from the PI controller, thereby diagnosing failure of the PI controller.

The current diagnosis part may transform information detected by a current detector, which detects a three-phase current output from the inverter, into two rotor fixing signals, and calculate a transformed current value, thereby diagnosing the failure of the PI controller.

The current diagnosis part may calculate an estimated current based on voltage calculated by the voltage diagnosis part, thereby diagnosing the failure of the PI controller.

The motor failure diagnosis system may further include a torque diagnosis part calculating torque based on a current output from a motor reference into which a torque command for operating the motor is input, and comparing torque input into the motor reference with torque calculated based on the current output from the motor reference, thereby diagnosing failure of the motor reference.

The torque diagnosis part may calculate transformation torque based on information detected by the current detector, thereby diagnosing the failure of the motor reference.

The torque diagnosis part may calculate estimated torque based on the current calculated by the current diagnosis part, thereby diagnosing the failure of the motor reference.

The motor failure diagnosis system may further include a voltage detector detecting voltage that is output from the inverter to the motor, and a pulse width modulation diagnosis part calculating duty from the voltage detected by the voltage detector, and comparing duty input into the inverter with duty calculated based on the voltage detected by the voltage detector, thereby diagnosing the failure of the inverter.

The voltage diagnosis part may calculate transformation voltage by transforming three-phase voltage detected by the voltage detector into two rotor fixing signals, thereby diagnosing the failure between the PI controller and the inverter.

The voltage diagnosis part may calculate estimated voltage based on duty calculated by the pulse width modulation diagnosis part, thereby diagnosing the failure between the PI controller and the inverter.

According to embodiments of the present disclosure, a motor failure diagnosis system includes a motor control device comprising an inverter that outputs a three-phase signal to a motor, a PI controller that receives current for operating the motor and outputs voltage, a first transformation that transforms voltage information of the PI controller into a vector and transmits the information, and a motor reference into which a torque command for operating the motor is input, and a motor failure diagnosis device diagnosing failure of at least one of the inverter, the PI controller, the first transformation, and the motor reference.

The motor failure diagnosis device may include a voltage detector that detects voltage output from the inverter to the motor, and calculate duty from the voltage detected by the voltage detector, thereby diagnosing failure of at least one of the inverter, the PI controller, the first transformation, and the motor reference.

According to embodiments of the present disclosure, a motor failure diagnosis method includes detecting three-phase voltage output from an inverter to a motor, diagnosing failure of the inverter based on the detected three-phase voltage, and diagnosing failure of a first transformation that transforms voltage information of a PI controller into a vector and transmits the information, based on diagnosed information on the failure of the inverter.

The diagnosing the failure of the inverter may include calculating duty based on the detected three-phase voltage, and comparing the calculated duty with duty input into the inverter.

The diagnosing the failure of the first transformation may include calculating voltage based on duty information that is input into the inverter, receiving voltage information that is output from the PI controller, and comparing voltage calculated based on the duty information input into the inverter with voltage output from the PI controller.

The diagnosing the failure of the first transformation may further include calculating estimated voltage based on the duty calculated in the diagnosing the failure of the inverter, and comparing the calculated estimated voltage with voltage output from the PI controller.

The motor failure diagnosis method may further include diagnosing failure of the PI controller based on information in the diagnosing the failure of the first transformation.

The diagnosing the failure of the PI controller may include calculating voltage output from the PI controller as a current, receiving the current input into the PI controller, comparing the current input into the PI controller with current calculated based on the voltage output from the PI controller, calculating estimated current based on voltage calculated in the diagnosing the failure of the first transformation, and comparing the calculated estimated current with the current input into the PI controller.

The motor failure diagnosis method may further include diagnosing failure of a motor reference into which a torque command for operating the motor is input, based on information in the diagnosing the failure of the PI controller.

According to embodiments of the present disclosure, a motor failure diagnosis system can effectively diagnose a failure in components that transmit information for operating a motor. Specifically, the motor failure diagnosis system can diagnose a failure by calculating and comparing information output by a front end of a component that transmits information based on the information of a final output end for operating a motor.

Further, the motor failure diagnosis system can effectively diagnose a failure in elements located at a front end in the process of transmitting final information for motor operation based on information from an output end of an inverter, after transmitting the information for motor operation.

### BRIEF DESCRIPTION OF THE DRAWINGS

FIG. 1 illustrates a configuration of a motor failure diagnosis system according to an embodiment of the present disclosure,

FIG. 2 illustrates a motor failure diagnosis process according to an embodiment of the present disclosure.

### DETAILED DESCRIPTION

Embodiments of the present disclosure will be described in detail with reference to the accompanying drawings such that those skilled in the art can easily practice the present disclosure. However, the present disclosure may be implemented in various ways without being limited to particular embodiments described herein.

It is to be noted that the drawings are schematic and not drawn to scale. The relative dimensions and proportions of parts in the drawings may be exaggerated or reduced in size for clarity and convenience in the drawings, and any dimensions are merely illustrative but are not restrictive. The same reference numerals are used throughout the drawings to designate the same or similar components.

Embodiments of the present disclosure specifically represent ideal embodiments of the present disclosure. As a result, various variations of the drawings are expected. Therefore, the embodiments are not limited to the specific shape of the illustrated area and also cover changes in shape due to manufacturing, for example.

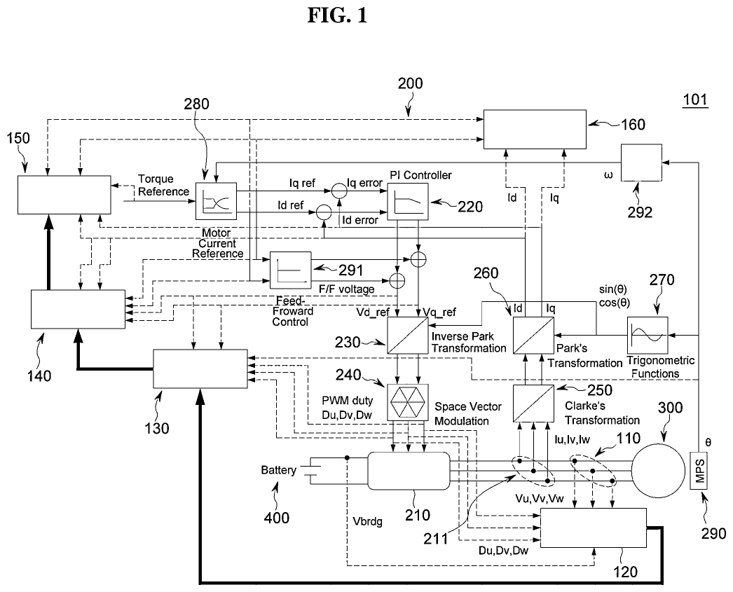

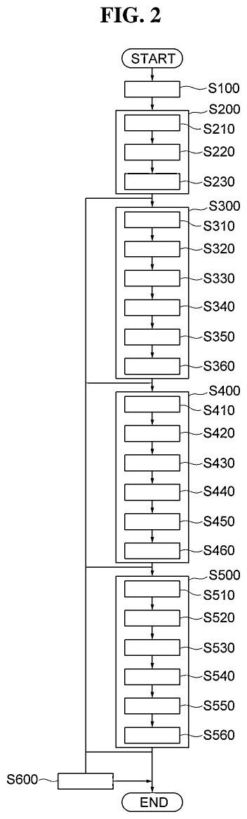

Hereinafter, a failure diagnosis system 101 of a motor 300 according to an embodiment of the present disclosure will be described with reference to FIGS. 1 and 2.

The motor 300 is a Permanent Magnet Synchronous Motor (PMSM), and rotates by obtaining a rotational force through attraction and repulsion between a permanent magnet and windings of a stator with the permanent magnet inserted into a rotor. As an example, such a motor 300 may be installed in a vehicle.

The failure diagnosis system 101 of the motor 300 according to an embodiment of the present disclosure includes a voltage diagnosis part 130.

The voltage diagnosis part 130 calculates voltage based on duty information input to an inverter 210, which outputs a three-phase signal to the motor 300. Specifically, the inverter 210 outputs the three-phase signal to the motor 300. Further, the inverter 210 is configured to convert direct current into alternating current.

Further, the voltage diagnosis part 130 receives voltage that is output from a PI controller 220. The voltage diagnosis part 130 compares voltage output from the PI controller 220 with voltage calculated based on the duty information input into the inverter 210.

Specifically, the voltage diagnosis part 130 may diagnose the inverter 210 as normal if an absolute value of a difference between voltage calculated based on the duty information input to the inverter 210 and voltage output from the PI controller 220 is within a set voltage reference range. For example, a motor control device 200 for controlling the motor 300 includes the inverter 210 and the PI controller 220.

Alternatively, if the absolute value of the difference between voltage calculated based on the duty information input to the inverter 210 and voltage output from the PI controller 220 is outside the set voltage reference range, the voltage diagnosis part 130 may diagnose that an error has occurred between the PI controller 220 and the inverter 210.

Thus, the motor failure diagnosis system 101 according to an embodiment of the present disclosure may diagnose a failure in a detailed configuration included in the motor control device 200 for controlling the motor 300. Specifically, the motor failure diagnosis system 101 according to an embodiment of the present disclosure may not detect a failure in sensors that detect information on the motor 300, but may effectively diagnose a failure in hardware or software of the detailed configuration of the motor control device 200 that drives the motor 300.

Further, the voltage diagnosis part 130 of the motor failure diagnosis system 101 according to the present disclosure may diagnose a failure in a first transformation 230.

The first transformation 230 may transform the voltage information of the PI controller 220 into a vector and transmit the vector. Specifically, the first transformation 230 may transform voltages Vd and Vq of the PI controller 220 into voltages Va and VB. That is, the first transformation 230 may be included in the motor control device 200, and software for generating a voltage vector may be preset.

As an example, the first transformation 230 may be an Inverse Park's Transformation.

Further, voltages Va and VB output through the first transformation 230 may pass through a space vector modulation 240. The space vector modulation 240 may generate a three-phase sinusoidal waveform for the windings of the motor 300 to control a pulse width for a switching device of the inverter 210. The space vector modulation 240 may output a plurality of control signals that adjust the rotational position or speed of the motor 300 based on the amplitude and angle of the voltage vector received from the first transformation 230.

That is, the voltage vector generated by the first transformation 230 may generate a pulse width modulation (PWM Duty) signal for controlling a switch of the inverter 210 through the space vector modulation 240. Such a signal may be a modulation voltage required to drive the motor 300 at a desired speed or torque.

Therefore, the motor failure diagnosis system 101 according to an embodiment of the present disclosure may effectively diagnose failures not only in hardware but also in preset software such as the first transformation 230.

The motor failure diagnosis system 101 according to an embodiment of the present disclosure may further include a current diagnosis part 140.

The current diagnosis part 140 may calculate the voltage output from the PI controller 220 as a current. Further, the current diagnosis part 140 may receive the current input into the PI controller 220. Moreover, the current diagnosis part 140 may compare the current input into the PI controller 220 with the current calculated based on the voltage output from the PI controller 220. Therefore, the current diagnosis part 140 may diagnose that there is an error in the PI controller 220.

Specifically, if the absolute value of the difference between the current calculated based on the voltage output from the PI controller 220 and the current input into the PI controller 220 is outside a set current reference range, the current diagnosis part 140 may diagnose that an error has occurred in the PI controller 220.

For example, the current diagnosis part 140 may calculate a current using the voltage output from the PI controller 220 through the motor voltage equation (Equation 1).

$$[ \begin{matrix}{V}_{d} \\ {V}_{q}\end{matrix} ] = [ \begin{matrix}{R}_{a} + \frac{d}{dt} {L}_{d} & - ω {L}_{q} \\ ω {L}_{d} & {R}_{a} + \frac{d}{dt} {L}_{q}\end{matrix} ] [ \begin{matrix}{i}_{d} \\ {i}_{q}\end{matrix} ] + [ \begin{matrix}0 \\ {ωΨ}_{a}\end{matrix} ] \qquad [ Equation 1 ]$$

Equation 1 may be pre-stored in the current diagnosis part 140. At this time, La and L_{q} are inductance parameters, Rₐ is a resistance value, and Va is a motor constant value. The current diagnosis part 140 includes pieces of information for calculating Equation 1.

Therefore, the motor failure diagnosis system 101 according to an embodiment of the present disclosure may diagnose the failure of the PI controller 220.

Further, the current diagnosis part 140 of the motor failure diagnosis system 101 according to an embodiment of the present disclosure may transform information detected by a current detector 211, which detects a three-phase current output from the inverter 210, into two rotor fixing signals, and calculate a transformed current value, thereby diagnosing the failure of the PI controller 220.

The current detector 211 may detect the three-phase current that is output from the inverter 210 and is transmitted to the motor 300. Further, the current detector 211 may transmit the information to the current diagnosis part 140.

The current diagnosis part 140 may transform the three-phase current transmitted from the current detector 211 into two rotor fixing signals, thereby calculating a transformed current value.

For example, the current diagnosis part 140 may transform the three-phase current into the two rotor fixing signals using Clarke's Transformation and Park's Transformation.

The Clarke's Transformation may transform the three-phase current vectors of Iu, Iv, and Iw into current vectors of Iα and Iβ, and the Park's Transformation may transform the current vector into currents of Id and Iq.

That is, the current diagnosis part 140 may calculate a transformation current by transforming the three-phase current vector transmitted from the current detector 211 into a DC current signal, using the pre-stored Clarke's Transformation and Park's Transformation.

Moreover, the current diagnosis part 140 may diagnose that the error of the PI controller 220 has occurred, when the absolute value of the difference between the transformed current obtained by transforming the three-phase current vector transmitted from the current detector 211 into the two rotor fixing signals and the current input into the PI controller 220 is outside a set current reference range.

That is, the current diagnosis part 140 may cross-check whether the PI controller 220 has failure through the above-described Clarke's Transformation and Park's Transformation.

Alternatively, the current diagnosis part 140 of the motor failure diagnosis system 101 according to an embodiment of the present disclosure may diagnose the failure of the PI controller 220 by calculating an estimated current based on the voltage calculated by the voltage diagnosis part 130.

The current diagnosis part 140 may calculate the estimated current using the above Equation 1 based on the voltage calculated by the voltage diagnosis part 130.

Further, the current diagnosis part 140 may diagnose that the error of the PI controller 220 has occurred, when the absolute value of the difference between the calculated estimated current and the current input into the PI controller 220 is outside the set current reference range.

That is, the current diagnosis part 140 may cross-check whether the PI controller 220 has failure through the calculated estimated current described above.

The motor failure diagnosis system 101 according to an embodiment of the present disclosure may further include a torque diagnosis part 150.

The torque diagnosis part 150 may calculate torque based on the current output from a motor reference 280 into which a torque command for operating the motor 300 is input. Further, the torque diagnosis part 150 may receive information about the torque input into the motor reference 280. Moreover, the torque diagnosis part 150 may diagnose the error of the motor reference 280 by comparing torque calculated based on the current output from the motor reference 280 with torque input into the motor reference 280.

For example, the torque command, angular velocity, control signal, etc. may be input into the motor reference 280.

Specifically, the torque diagnosis part 150 may diagnose that the error of the motor reference 280 has occurred, when the absolute value of the difference between torque calculated based on the currents i_{d} and i_{q} output from the motor reference 280 and torque input into the motor reference 280 is outside a set torque reference range.

For example, the torque diagnosis part 150 may calculate torque using current output from the motor reference 280 through the motor torque equation (Equation 2).

$$T = \frac{3}{2} \frac{P}{2} \{ {Ψ}_{a} {i}_{q} + ( {L}_{d} {i}_{d} ) {i}_{q} - ( {L}_{q} {I}_{q} ) {i}_{d} \} \qquad [ Equation 2 ]$$

Equation 2 may be pre-stored in the torque diagnosis part 150. At this time, L_{d} and L_{q} are inductance parameters, P is an output value, and ψₐ is a motor constant value. The current diagnosis part 140 includes pieces of information for calculating Equation 2.

Further, the torque diagnosis part 150 calculates transformation torque using Equation 2 by transforming the current in the output end of the inverter 210 detected by the current detector 211 through the Clarke's Transformation and the Park's Transformation to calculate the transformation current.

Further, the torque diagnosis part 150 calculate estimated torque using Equation 2 based on the current calculated by the current diagnosis part 140.

Moreover, the torque diagnosis part 150 may diagnose the failure of the motor reference 280 by comparing the calculated torque, transformation torque, and estimated torque and cross-verifying the currents. In other words, the torque diagnosis part 150 may use information output through the motor reference 280 and information from the final output end of the inverter 210 as cross-verification for the failure diagnosis, thereby effectively determining the failure location of the motor control device 200.

The motor failure diagnosis system 101 according to an embodiment of the present disclosure may further include a voltage detector 110 and a pulse width modulation diagnosis part 120.

The voltage detector 110 may detect a voltage output from the inverter 210 to the motor 300. Specifically, the voltage detector 110 may detect the three-phase voltage that is output from the inverter 210 and is input into the motor 300.

The pulse width modulation diagnosis part 120 may receive voltage information detected by the voltage detector 110. Further, the pulse width modulation diagnosis part 120 may calculate the duty using the voltage detected by the voltage detector 110. Specifically, the pulse width modulation diagnosis part 120 receives pulse width modulation duty information that is output from the space vector modulation 240 and is input into the inverter 210.

Moreover, the pulse width modulation diagnosis part 120 may receive duty information that is input into the inverter 210.

The pulse width modulation duty (PWM Duty) may be calculated using the voltage detected by the voltage detector 110.

For example, the pulse width modulation diagnosis part 120 may calculate the duty using Equation 3 based on the voltage detected by the voltage detector 110.

$$Du ’ = Vu / ( √ 3 Vbrdg ) , Dv ’ = Vv / ( √ 3 Vbrdg ) , Dw ’ = Vw / ( √ 3 Vbrdg ) \qquad [ Equation 3 ]$$

Equation 3 may be pre-stored in the pulse width modulation diagnosis part 120.

Vu, Vv, and Vw are a three-phase voltage that is input into the motor 300. Vbrdg may be a bridge voltage between a battery 400 that is connected to the inverter 210 to supply power and the inverter 210.

Du′, Dv′, and Dw′ may be the calculated pulse width modulation duty.

Specifically, the pulse width modulation diagnosis part 120 may diagnose that the error of the inverter 210 has occurred, when the absolute value of a difference between the calculated pulse width modulation duty and the pulse width modulation duty input into the inverter 210 is outside a set duty reference range.

Further, the voltage diagnosis part 130 of the motor failure diagnosis system 101 according to an embodiment of the present disclosure may transform the three-phase voltage detected by the voltage detector 110 into two rotor fixing signals, thereby calculating the transformation voltage.

The voltage detector 110 may calculate transformation voltage by transforming the three-phase voltage detected by the voltage diagnosis part 130 through the Clarke's Transformation and the Park's Transformation into two rotor fixing signals.

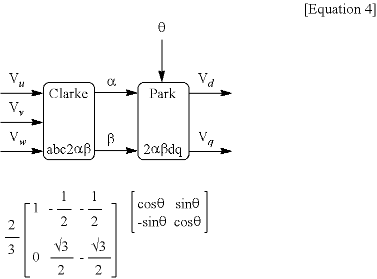

Equation 4 may be pre-stored in the voltage diagnosis part 130.

Vu, Vv, and Vw are three-phase voltages input into the motor 300. θ is a value detected by a motor location detector 290, which detects the rotation angle of the motor 300.

Clarke's Transformation may transform the vectors of the three-phase voltages Vu, Vv, and Vw into voltage vectors of Vα and Vβ, while Park's Transformation may transform voltage vectors into voltages of Vd and Vq.

Specifically, Equation 4 may be a formula for calculating the transformation of a rotary coordinate system into a stationary coordinate system, which transforms the three-phase voltages of u, v, and w into two phases of alpha and beta and optimally two phases of d and q. That is, Equation 4 may be the transformation formula of the Clarke and Park transformation.

Alternatively, the voltage diagnosis part 130 of the motor failure diagnosis system 101 according to an embodiment of the present disclosure may calculate estimated voltage based on the duty calculated by the pulse width modulation diagnosis part 120.

The voltage diagnosis part 130 may receive duty information calculated by the pulse width modulation diagnosis part 120 and calculate an estimated voltage. Specifically, the voltage diagnosis part 130 may calculate the voltages of two rotor fixing signals using the calculated three-phase duty through Park's transformation and inverse space vector modulation, which are inverse transformation of the space vector modulation.

The voltage diagnosis part 130 may transform the calculated pulse width modulation duty of Du′, Dv′, Dw′ into Va and VB through the inverse space vector modulation 240 and into two rotor fixing voltages through a third transformation 260.

Therefore, the voltage diagnosis part 130 may calculate the estimated voltage using the Inverse Space Vector Modulation 240 and the Park's Transformation based on the calculated pulse width modulation duty of Du′, Dv′, Dw′.

Alternatively, when the absolute value of a difference between the calculated estimated voltage and the voltage output by the PI controller 220 is outside a set voltage reference range, the voltage diagnosis part 130 may diagnose that an error has occurred between the PI controller 220 and the inverter 210.

For example, the voltage diagnosis part 130 may effectively diagnose whether an error has occurred between the PI controller 220 and the inverter 210 by comparing the calculated estimated voltage, the voltage output from the PI controller 220, and the calculated transformation voltage described above.

The motor failure diagnosis system 101 according to an embodiment of the present disclosure may include the motor control device 200 and the motor failure diagnosis device 100.

The motor control device 200 may include the inverter 210, the PI controller 220, the first transformation 230, and the motor reference 280.

The inverter 210 may output a three-phase signal to the motor 300. The PI controller 220 may receive current for operating the motor 300 and output voltage. The first transformation 230 may transform voltage information output by the PI controller 220 into the vector and transmit the vector. The motor reference 280 may receive a torque command for operating the motor 300.

Specifically, the torque command information received by the motor reference 280 may be transmitted to the PI controller 220. Specifically, the motor reference 280 may receive the torque command for operating the motor 300 and transmit a corresponding current to the PI controller 220.

The motor failure diagnosis device 100 may diagnose the failure in any one of the inverter 210, the PI controller 220, the first transformation 230, and the motor reference 280. Specifically, the motor failure diagnosis device 100 may diagnose the failure in a plurality of components included in the motor control device 200.

Therefore, the motor failure diagnosis device 100 according to an embodiment of the present disclosure may further include the voltage detector 110.

The voltage detector 110 may detect voltage that is output from the inverter 210 to the motor 300. Specifically, the voltage detector 110 may detect voltage that is input into the motor 300. That is, the voltage detector 110 may detect voltage in the output end of the inverter 210.

Further, the motor failure diagnosis device 100 may diagnose the failure in one or more components included in the motor control device 200 based on information obtained by calculating the duty from the voltage detected by the voltage detector 110.

Specifically, the motor failure diagnosis device 100 may effectively diagnose failure in components or programs in which failure has occurred, by calculating input/output information between the components to diagnose the failure in each component of the motor control device 200 based on information detected from the output end of the inverter 210.

That is, the motor failure diagnosis system 101 according to an embodiment of the present disclosure may effectively diagnose failure in elements of the front end in a process where final information for operating the motor 300 is transmitted based on the information from the output end of the inverter 210 after transmitting information for operating the motor 300.

The motor control device 200 according to an embodiment of the present disclosure may further include a current detector 211, a second transformation 250, a third transformation 260, a space vector modulation 240, a motor location detector 290, an rpm counter 292, and a motor controller 160.

The current detector 211 may detect a three-phase current that is input from the inverter 210 to the motor 300.

The second transformation 250 may be Clarke's Transformation. Clarke's Transformation may transform the vectors of the three-phase currents Iu, Iv, and Iw into the current vectors of Iα and Iβ. Specifically, information detected by the current detector 211 may be transmitted to the second transformation 250.

The third transformation 260 may be Park's Transformation. Specifically, the transformed current vector may be transformed into currents of Id and Iq by Park's Transformation. Specifically, the current vector information transformed by the second transformation 250 may be transmitted to the third transformation 260.

The motor controller 160 may receive the current information transformed by the third transformation 260 and check whether the motor 300 is operated in a required state.

The motor location detector 290 may detect the rotation angle of the motor 300. The information detected by the motor location detector 290 may be transmitted to the rpm counter 292 to calculate the angular velocity of the motor 300 and then calculate the rotation angle of the motor 300.

The motor controller 160 may transmit information that is currently required for operating the motor 300 or receive current information transformed by the third transformation 260 of the motor 300. Further, when the motor failure diagnosis device 100 determines that any one of the components of the motor control device 200 has failure, the motor controller 160 may control the motor 300 to operate the motor based on information other than information output by the component having failure.

Alternatively, when the motor controller 160 determines that there is failure from the motor failure diagnosis device 100, the failure may be notified to a driver. For example, the driver may receive visual information such as an image, lighting of a lamp, or text, or auditory information that failure has occurred in the component of the motor control device 200. Alternatively, the driver may be informed that inspection is needed.

Further, the motor control device 200 according to an embodiment of the present disclosure may further include a trigonometric function 270.

The trigonometric function 270 may transform and transmit information detected by the motor location detector 290, which detects the rotation angle of the motor 300 using the third transformation 260 or the first transformation 230.

The motor control device 200 according to an embodiment of the present disclosure may further include a feed forward controller 291.

The feed forward controller 291 may receive information required for the motor 300 to change an input value according to the current output state of the motor 300.

The motor control device 200 according to an embodiment of the present disclosure may further include a battery 400.

The battery 400 may supply power for the operation of the inverter 210. For example, the battery 400 may be a battery 400 installed in the vehicle.

With this configuration, the motor failure diagnosis system 101 according to an embodiment of the present disclosure may effectively diagnose the failure location of each component of the motor control device 200 using information from the final output end of the inverter 210 for the operation of the motor 300. Specifically, a module having failure in the motor control device 200 may be effectively diagnosed by comparing information output from the front end of each component with information of a component located at a rear end through calculation.

That is, the motor failure diagnosis system 101 may effectively determine the failure location using the feedback information of each component of the motor control device 200.

Hereinafter, a diagnosis method of a motor failure diagnosis system 101 according to another embodiment of the present disclosure will be described with reference to FIGS. 1 and 2.

The voltage detector 110 detects the three-phase voltage output from the inverter 210 to the motor 300 (S100). Specifically, the voltage detector 110 detects voltage at the output end of the inverter 210.

The failure of the inverter 210 is diagnosed based on the detected three-phase voltage (S200). Specifically, the pulse width modulation diagnosis part 120 receives the three-phase voltage detected by the voltage detector 110 (S210). The pulse width modulation diagnosis part 120 calculates the three-phase voltage detected by the voltage detector 110 as the duty (S220).

Further, the pulse width modulation diagnosis part 120 may diagnose the failure of the inverter 210 by comparing the calculated duty with the duty input into the inverter 210 (S220). Specifically, the pulse width modulation diagnosis part 120 may calculate the three-phase voltage detected by the voltage detector 110 as the PWM Duty (Pulse Width Modulation Duty) based on the above Equation 3 and then compare the duty with the duty input into the inverter 210.

In this regard, the pulse width modulation diagnosis part 120 may receive a bridge voltage Vbfdg transmitted from the battery 400 to the inverter 210 and use the voltage for calculation.

That is, the pulse width modulation diagnosis part 120 may diagnose the failure of the inverter 210 with Duty range min<abs (calculated duty−duty input into the inverter 210)<Duty range max. The pulse width modulation diagnosis part 120 may determine whether the absolute value of a difference between the calculated duty and the duty input into the inverter 210 is within a range from a preset lowest duty to a preset highest duty.

The diagnosis result of the pulse width modulation diagnosis part 120 may be transmitted to the motor controller 160.

Based on the failure diagnosis information of the inverter 210, the failure between the inverter 210 and the PI controller 220 is diagnosed (S300). Specifically, the voltage diagnosis part 130 calculates voltage based on the duty information input into the inverter 210 (S310). Further, the voltage diagnosis part 130 receives voltage output from the PI controller 220 (S320). Moreover, the voltage diagnosis part 130 compares the voltage output from the PI controller 220 with the calculated voltage (S330).

That is, the voltage diagnosis part 130 may diagnose failure between the inverter 210 and the PI controller 220 with the Voltage range min<abs (calculated voltage−voltage output from the PI controller 220)<Voltage range max. The voltage diagnosis part 130 may determine whether the absolute value of a difference between the calculated voltage and the voltage output from the PI controller 220 is within a range from a preset lowest voltage to a preset highest voltage.

Further, the voltage diagnosis part 130 calculates an estimated voltage based on the duty information calculated by the pulse width modulation diagnosis part 120 (S340). Specifically, the voltage diagnosis part 130 may calculate the estimated voltage by calculating the duty calculated by the pulse width modulation diagnosis part 120 based on space vector modulation and Inverse Park transformation.

Further, the voltage diagnosis part 130 receives the three-phase voltage from the output end of the inverter 210 detected by the voltage detector 110 to calculate transformation voltage based on Clarke's Transformation and Park's Transformation (S350). For example, the voltage diagnosis part 130 may calculate the transformation voltage through Equation 4.

That is, the voltage diagnosis part 130 may diagnose the failure of the first transformation 230 by comparing the calculated voltage, the estimated voltage, and the transformation voltage and cross-verifying the voltage (S360). In other words, the voltage diagnosis part 130 may use the final output-end information of the inverter 210 as cross-verification for failure diagnosis, thereby effectively determining the failure location of the motor control device 200.

For example, the voltage diagnosis part 130 may determine that an error has occurred in the module outputting the value, when any one of the calculated voltage, the estimated voltage, and the transformation voltage is outside a set value.

The failure of the PI controller 220 is diagnosed (S400). Specifically, the current diagnosis part 140 receives the voltage output from the PI controller 220 to calculate it as the current using Equation 1 (S410). Further, the current diagnosis part 140 receives current input into the PI controller 220 (S420). The current diagnosis part 140 compares current input into the PI controller 220 with the calculated current (S430).

That is, the current diagnosis part 140 may diagnose the failure of the PI controller 220 with Current range min<abs (calculated current-current input into the PI controller 220)<Current range max. The current diagnosis part 140 may determine whether the absolute value of a difference between the calculated current and the current input into the PI controller 220 is within a range from a preset lowest current to a preset highest current.

Further, the current diagnosis part 140 calculates the estimated current using Equation 1 based on the voltage calculated by the voltage diagnosis part 130 (S440).

Further, the current diagnosis part 140 calculates transformation current using Clarke's Transformation and Park's Transformation from the current at the output end of the inverter 210 detected by the current detector 211 (S450).

The current diagnosis part 140 may diagnose the failure of the PI controller 220 by comparing the calculated current, the estimated current, and the transformation current and cross-verifying the current (S460). In other words, the current diagnosis part 140 may use the information output through the PI controller 220 and the final output-end information of the inverter 210 as cross-verification for failure diagnosis, thereby effectively determining the failure location of the motor control device 200.

The failure of the motor reference 280 receiving the torque information input for the operation of the motor 300 is diagnosed (S500). Specifically, the torque diagnosis part 150 calculates torque using Equation 2 from the current output from the motor reference 280 (S510). The torque diagnosis part 150 receives torque that is input into the motor reference 280 (S520).

Further, the torque diagnosis part 150 compares the calculated torque with the torque input into the motor reference 280 (S530).

The torque diagnosis part 150 may diagnose the failure of the motor reference 280 with Torque range min<abs (calculated torque−torque input into the motor reference 280)<Torque range max. The torque diagnosis part 150 may determine whether the absolute value of a difference between the calculated torque and the torque input into the motor reference 280 is within a range from a preset lowest torque to a preset highest torque.

Further, the torque diagnosis part 150 calculates transformation torque using Equation 2 by calculating the transformation current using Clarke's Transformation and Park's Transformation from the current at the output end of the inverter 210 detected by the current detector 211 (S540).

Further, the torque diagnosis part 150 calculates the estimated torque using Equation 2 based on the current calculated by the current diagnosis part 140 (S550).

Moreover, the torque diagnosis part 150 may diagnose the failure of the motor reference 280 by comparing the calculated torque, the transformation torque, and the estimated torque and cross-verifying the current (S560). In other words, the torque diagnosis part 150 may use the information output through the motor reference 280 and the final output-end information of the inverter 210 as cross-verification for failure diagnosis, thereby effectively determining the failure location of the motor control device 200.

When it is determined that failure has occurred in a component diagnosed by each of the above-described torque diagnosis part 150, current diagnosis part 140, voltage diagnosis part 130, and pulse width modulation diagnosis part 120, this information is provided to the motor controller 160 and an alarm part is operated to output warning information to a driver (S600).

Specifically, based on the failure diagnosis result of the motor 300 transmitted to the motor controller 160, the motor controller 160 may limit the driving conditions of the motor 300 or perform calculation based on information on other modules while ignoring information on a detailed module that has failed.

Therefore, the failure diagnosis method of the motor 300 according to an embodiment of the present disclosure can determine the failure of a preceding module based on information from the output end of the inverter 210, thereby effectively diagnosing a failure location among the errors of a single module or software.

Specifically, the failure diagnosis method of the motor 300 according to an embodiment of the present disclosure does not simply compare two pieces of information or one piece of information with a preset value, but can cross-verify pieces of information calculated or detected using information at the final output end.

Thus, the control device 200 of the motor 300 can control the motor 300 by excluding information output by the faulty module and replacing the information to be output by the faulty module with the calculated value.

Although embodiments of the present disclosure have been described above with reference to the accompanying drawings, those skilled in the art will understand that the present disclosure may be implemented in other specific forms without changing its technical idea or essential features.

Therefore, it should be noted that the above-described embodiments are illustrative in all respects but are not restrictive. The scope of the present disclosure is defined by the claims described below, and all changes or modifications derived from the meaning and scope of the claims and their equivalent concepts should be interpreted as being included in the scope of the present disclosure.

### DETAILED DESCRIPTION OF MAIN ELEMENTS

| | |
|---|---|
| 100: motor failure diagnosis device | 101: motor failure diagnosis system |
| 200: motor control device | 300: motor |
| 110: voltage detector | 120: inverter |
| 130: voltage diagnosis part | 140: current diagnosis part |
| 150: torque diagnosis part | 400: battery |
| 210: inverter | 211: current detector |
| 220: PI controller | 230: first transformation |
| 280: motor reference | |

What is claimed is:

1. A motor failure diagnosis system comprising:
a voltage diagnosis part calculating voltage based on duty information input into an inverter that outputs a three-phase signal to a motor, and comparing voltage output from a PI controller that receives current for operating the motor and outputs voltage, with voltage calculated based on the duty information input into the inverter, thereby diagnosing failure between the PI controller and the inverter.

2. The motor failure diagnosis system of claim 1, wherein the voltage diagnosis part diagnoses failure of a first transformation that transforms voltage information of the PI controller into a vector and transmits the information.

3. The motor failure diagnosis system of claim 1, further comprising:
a current diagnosis part calculating the voltage output from the PI controller as a current, and comparing a current input into the PI controller with the current calculated based on the voltage output from the PI controller, thereby diagnosing failure of the PI controller.

4. The motor failure diagnosis system of claim 3, wherein the current diagnosis part transforms information detected by a current detector, which detects a three-phase current output from the inverter, into two rotor fixing signals, and calculates a transformed current value, thereby diagnosing the failure of the PI controller.

5. The motor failure diagnosis system of claim 3, wherein the current diagnosis part calculates an estimated current based on voltage calculated by the voltage diagnosis part, thereby diagnosing the failure of the PI controller.

6. The motor failure diagnosis system of claim 4, further comprising:
a torque diagnosis part calculating torque based on a current output from a motor reference into which a torque command for operating the motor is input, and comparing torque input into the motor reference with torque calculated based on the current output from the motor reference, thereby diagnosing failure of the motor reference.

7. The motor failure diagnosis system of claim 6, wherein the torque diagnosis part calculates transformation torque based on information detected by the current detector, thereby diagnosing the failure of the motor reference.

8. The motor failure diagnosis system of claim 6, wherein the torque diagnosis part calculates estimated torque based on the current calculated by the current diagnosis part, thereby diagnosing the failure of the motor reference.

9. The motor failure diagnosis system of claim 1, further comprising:
a voltage detector detecting voltage that is output from the inverter to the motor; and
a pulse width modulation diagnosis part calculating duty from the voltage detected by the voltage detector, and comparing duty input into the inverter with duty calculated based on the voltage detected by the voltage detector, thereby diagnosing the failure of the inverter.

10. The motor failure diagnosis system of claim 9, wherein the voltage diagnosis part calculates transformation voltage by transforming three-phase voltage detected by the voltage detector into two rotor fixing signals, thereby diagnosing the failure between the PI controller and the inverter.

11. The motor failure diagnosis system of claim 9, wherein the voltage diagnosis part calculates estimated voltage based on duty calculated by the pulse width modulation diagnosis part, thereby diagnosing the failure between the PI controller and the inverter.

12. A motor failure diagnosis system comprising:
a motor control device comprising an inverter that outputs a three-phase signal to a motor, a PI controller that receives current for operating the motor and outputs voltage, a first transformation that transforms voltage information of the PI controller into a vector and transmits the information, and a motor reference into which a torque command for operating the motor is input; and
a motor failure diagnosis device diagnosing failure of at least one of the inverter, the PI controller, the first transformation, and the motor reference.

13. The motor failure diagnosis system of claim 1, wherein the motor failure diagnosis device comprises a voltage detector that detects voltage output from the inverter to the motor, and calculates duty from the voltage detected by the voltage detector, thereby diagnosing failure of at least one of the inverter, the PI controller, the first transformation, and the motor reference.

14. A motor failure diagnosis method comprising:
detecting three-phase voltage output from an inverter to a motor;
diagnosing failure of the inverter based on the detected three-phase voltage; and
diagnosing failure of a first transformation that transforms voltage information of a PI controller into a vector and transmits the information, based on diagnosed information on the failure of the inverter.

15. The motor failure diagnosis method of claim 14, wherein the diagnosing the failure of the inverter comprises:
calculating duty based on the detected three-phase voltage; and
comparing the calculated duty with duty input into the inverter.

16. The motor failure diagnosis method of claim 14, wherein the diagnosing the failure of the first transformation comprises:
calculating voltage based on duty information that is input into the inverter;
receiving voltage information that is output from the PI controller; and
comparing voltage calculated based on the duty information input into the inverter with voltage output from the PI controller.

17. The motor failure diagnosis method of claim 15, wherein the diagnosing the failure of the first transformation further comprises:
calculating estimated voltage based on the duty calculated in the diagnosing the failure of the inverter; and
comparing the calculated estimated voltage with voltage output from the PI controller.

18. The motor failure diagnosis method of claim 15, further comprising:
diagnosing failure of the PI controller based on information in the diagnosing the failure of the first transformation.

19. The motor failure diagnosis method of claim 18, wherein the diagnosing the failure of the PI controller comprises:
calculating voltage output from the PI controller as a current;
receiving the current input into the PI controller;
comparing the current input into the PI controller with current calculated based on the voltage output from the PI controller;
calculating estimated current based on voltage calculated in the diagnosing the failure of the first transformation; and
comparing the calculated estimated current with the current input into the PI controller.

20. The motor failure diagnosis method of claim 18, further comprising:
diagnosing failure of a motor reference into which a torque command for operating the motor is input, based on information in the diagnosing the failure of the PI controller.
